(19) United States
(12) Patent Application Publication
(10) Pub. No.: US 2009/0061596 A1
(43) Pub. Date: Mar. 5, 2009

(54) EXPANDING TOOL, EXPANDING METHOD, AND MANUFACTURING METHOD OF UNIT ELEMENTS

(75) Inventors: Wataru TAKAHASHI, Chino-shi (JP); Takayoshi MIZUNO, Shiojiri-shi (JP)

Correspondence Address: Workman Nydegger;1000 Eagle Gate Tower, 60 East South Temple, Salt Lake City, UT, 84111, US

(73) Assignee: SEIKO EPSON CORPORATION, Tokyo (JP)

(21) Appl. No.: 12/197,418

(22) Filed: Aug. 25, 2008

(30) Foreign Application Priority Data
Aug. 27, 2007 (JP) 2007-220319

(51) Int. Cl. H01L 21/304; B24B 23/02; B24B 1/00

(52) U.S. Cl. 438/460; 451/358; 451/58; 257/E21.237

(57) ABSTRACT

There is provided an expanding tool used for dividing a wafer on an expanding tape by applying a radial tensile force to the expanding tape. The expanding tool includes a dividing frame having a first opening, an outer expanding ring having a contact portion that can be made contact with the dividing frame, the contact portion being provided at an outer periphery side of the outer expanding ring, and having a second opening smaller than the first opening, and an inner expanding ring having an outer shape smaller than the second opening.

### BACKGROUND

1. Technical Field

The present invention relates to an expanding tool, an expanding method, and a method for manufacturing unit elements, and in particular is usefully applied when a number of unit elements such as electronic parts or the like formed on a silicon wafer are diced.

2. Related Art

In a manufacturing process of a semiconductor element or the like, a number of unit elements (IC chips or the like) each having a same structure as an individual functional part are formed on one wafer. Herein, the wafer on which the unit elements are formed is diced into separate unit elements by a dividing process. Such a dividing is performed by adhering a wafer on which the unit elements are formed to an expanding tape having stretch properties, and thereafter making parting lines on the wafer by a thin whetstone so called a blade, and then applying a tensile force to the expanding tape in radiation direction.

FIGS. 6A to 6E are each a plan view showing each part of an expanding toll used in the dividing process, in particular when applying a tensile force to the expanding tape in radiation direction. A dividing frame 1 shown in FIG. 6A has cutouts 1a for positioning and is formed by a rigid body (metal in a usual case) having a circular opening 1b whose diameter is larger than the outer diameter of a wafer 3 at the center. An expanding tape 2 shown in FIG. 6B is a member having stretch properties and an adhesive agent is applied on a surface thereof. An orientation flat 3a for positioning is formed in the wafer 3 shown in FIG. 6C, and a number of unit elements 4 such as IC chips or the like are integrally formed on the wafer 3. An outer expanding ring 5 shown in FIG. 6D is a circular ring member whose inner diameter is Φ1. An inner expanding ring 6 shown in FIG. 6E is a circular ring member whose outer diameter is Φ2. Herein, the outer diameter Φ2 is slightly smaller than the inner diameter Φ1.

FIGS. 7A to 7E are each a plan view showing each process when an expanding is performed by using the expanding tool according to a conventional technique. Each process will be described based on FIGS. 7A to 7E.

1) First, the expanding tape 2 is adhered to the dividing frame 1 having predetermined rigidity preferable for transporting, and the wafer 3 that is integrated with the unit elements 4 is mounted at a predetermined position of the expanding tape 2 (see FIG. 7A). To be more specific, a circumference margin of the expanding tape 2 is bonded to the lower surface of the dividing frame 1 in the state where the adhesion surface of the expanding tape 2 is oriented in the upper direction. Then, the wafer 3 and the expanding tape 2 are bonded by placing the wafer 3 at a predetermined position of the adhesive face of the expanding tape 2.

2) Parting lines 7 for separating the adjacent unit elements 4 are formed by a dicer, a cleaving device, or the like (see FIG. 7B).

3) A tensile force is applied to the expanding tape 2 in radiation direction by inserting the outer expanding ring 5 and the inner expanding ring 6 in the expanding tape 2. By the application of the tensile force, the wafer 3 is perfectively separated along the parting lines 7 shown in FIG. 7B, and a space 8 is formed between the adjacent unit elements 4 (see FIG. 7C). To be more specific, the inner expanding ring 6 is made contact with the back surface of the expanding tape 2 form the lower direction of the expanding tape 2 and the inner expanding ring 6 is lifted, and at the same time, the outer expanding ring 5 is lowered from the upper direction of the expanding tape 2 to fit the inner expanding ring 6 in the outer expanding ring 5. Herewith, the expanding tape 2 is sandwiched between the inner periphery of the outer expanding ring 5 and the outer periphery of the inner expanding ring 6. As a result, a tensile force corresponding to a raised amount of the inner expanding ring 6 is applied to the expanding tape 2 in radiation direction. Herein, a small margin is provided between the inner diameter Φ1 of the outer expanding ring 5 and the outer diameter Φ2 of the inner expanding ring 6, so that the expanding tape 2 can be favorably sandwiched between the inner periphery of the outer expanding ring 5 and the outer periphery of the inner expanding ring 6.

4) By the application of a tensile force with respect to the expanding tape 2, the expanding tape 2 adhered to the dividing frame 1 is peeled off in the process shown in FIG. 7C. Herein, since the outer diameter of the outer expanding ring 5 is smaller than the diameter of the opening 1b of the dividing frame 1, the expanding tape 2 on which the outer expanding ring 5, the inner expanding ring 6, and the wafer 3 are mounted is separated from the dividing frame 1 as an integrated one. Then, a needless portion of the expanding tape 2 that is protruded from the outer expanding ring 5 is cut to have a shape of the expanding tape 2 on which the integrated outer expanding ring 5, inner expanding ring 6, and wafer 3 are mounted (see FIG. 7D).

5) The unit elements 4 are picked up from the diced wafer 3 to transport the unit elements 4 for a post-process (see FIG. 7E).

Note that JP-A-2000-71465 (see FIG. 4A) can be included as a printed publication that discloses the same type of expanding tool.

In the expanding process performed by using the expanding tool according to the conventional technique, the expanding tape 2 mounting the outer expanding ring 5, the inner expanding ring 6, and the wafer 3 are separated from the dividing frame 1 as an integrated one in the aforementioned process 4). Accordingly, a relative positional relationship between the outer expanding ring 5 and the wafer 3 and between the inner expanding ring 6 and the wafer 3 are maintained at a predetermined relationship. However, it is very difficult to perform positioning with respect to another part with the outer expanding ring 5 and the inner expanding ring 6 having a circular shape. Accordingly, it is necessary to perform a predetermined operation after picking up the unit elements 4 and transporting the unit elements 4 for a next process. That is, since the wafer 3 can not be transported as the unit of the wafer 3, when it is necessary to manage the wafer 3 as a unit, it is necessary to cope with traceability or the like. Accordingly, there is a problem to construct a process which makes it possible to provide smooth and speedy processing. Incidentally, in the conventional technique, even though a number of unit elements 4 are fixed on the expanding tape 2, the unit elements 4 are separately picked up and moved to another tray or the like in the aforementioned process 5). Accordingly, it is difficult to collectively moving the unit elements 4 in many cases.

### SUMMARY

An advantage of some aspects of the invention is to provided an expanding tool, an expanding method, and a method for manufacturing unit elements which makes it possible to perform a predetermined processing after transporting a dividing frame, expanding rings, a wafer, and the like in an integrated state for a post-process.

According to an aspect of the invention, there is provided an expanding tool used for dividing a wafer on an expanding tape by applying a radial tensile force to the expanding tape. The expanding tool includes a dividing frame having a first opening, an outer expanding ring having a contact portion that can be made contact with the dividing frame, the contact portion being provided at an outer periphery side of the outer expanding ring, and having a second opening smaller than the first opening, and an inner expanding ring having an outer shape smaller than the second opening.

According to the aspect, the outer expanding ring can be made contact with the dividing frame. Accordingly, the outer expanding ring can be pushed to the dividing frame by a reaction force from the expanding tape in the state where the expanding tape is sandwiched between the inner periphery of the outer expanding ring and the outer periphery of the inner expanding ring to apply a tensile force to the expanding tape in radiation direction. As a result, the expanding tape on which the unit elements are adhered can be integrated with the dividing frame even after the wafer is diced. Consequently, the unit elements can be transferred for a post-process with the dividing frame. Accordingly, not only the transport can be easily performed, but also positioning or the like in a post-process can be easily performed. This largely contributes for rationalization of operation.

Herein, it is preferable that each of the first opening and the second opening has a circular shape and the inner expanding ring is a circular ring. Because, this may enables to uniform the radial tensile force to be applied as far as possible.

Further, as concrete examples, it is preferable that a plurality of the contact portions are provided so as to be dispersed in a circumference direction of the outer expanding ring, the contact portion is provided along the entire periphery of the outer expanding ring, or the contact portion is formed by a lower surface of an outer margin of the outer expanding ring by increasing an outer shape of the outer expanding ring than the first opening. A preferable one can be selected from the examples in consideration for a reaction force from the expanding tape.

According to another aspect of the invention, there is provided an expanding method including adhering an expanding tape on a lower surface of an inner margin of a dividing frame having a first opening whose shape is larger than an outer diameter of a wafer at a center, mounting the wafer that is integrated with a plurality of unit elements at a predetermined position of the expanding tape, and forming parting lines so that the adjacent unit elements are separated on the wafer, and contacting an inner expanding ring with a back surface of the expanding tape from one direction of the expanding tape, and at the same time, contacting an outer expanding ring which is a member having a second opening whose inner shape is larger than an outer shape of the inner expanding ring with the expanding tape from another direction of the expanding tape, and fitting the inner expanding ring to an inside of the outer expanding ring in the state where a contact portion of the outer expanding ring is made contact with the dividing frame, thereby applying a radial tensile force to the expanding tape to dice the wafer.

According to the aspect, transport can be performed for a post-process without separating the dividing frame, the outer expanding frame, the inner expanding frame, and the like. As a result, effects described below can be provided.

1) A predetermined processing can be speedy and easily performed by performing the predetermined processing after positioning is performed by using a positioning groove of the dividing frame or the like when measuring a pattern in the unit elements after expanding.

2) An operation such as die attach, wire bonding, or the like can be performed in the same way.

3) Since the unit elements can be transported for every wafer, a predetermined administration can be easily performed even when there is a large variation in quality or the like for every wafer.

4) The unit element that is a finished product is adhered to the expanding tape. Accordingly, chipping or the like is difficult to occur as compared with a chip tray transporting. Accordingly, a preferable transport can be provided.

5) Even when the unit element is picked up right after expanding, since the unit element is integrated with the dividing frame, it is easy to fix the unit element.

According to still another aspect of the invention, there is provided a method for manufacturing unit elements including adhering an expanding tape on a lower surface of an inner margin of a dividing frame having a first opening whose shape is larger than an outer diameter of a wafer at a center, mounting the wafer that is integrated with a plurality of unit elements at a predetermined position of the expanding tape, and forming parting lines so that the adjacent unit elements are separated on the wafer, and contacting an inner expanding ring with a back surface of the expanding tape from one direction of the expanding tape, and at the same time, contacting an outer expanding ring which is a member having a second opening whose inner shape is larger than an outer shape of the inner expanding ring with the expanding tape from another direction of the expanding tape, and fitting the inner expanding ring to an inside of the outer expanding ring in the state where a contact portion of the outer expanding ring is made contact with the dividing frame, thereby applying a radial tensile force to the expanding tape to dice the wafer.

According to the aspect, transport can be performed for a post-process without separating the dividing frame, the outer expanding frame, the inner expanding frame, and the like in a process for manufacturing unit elements. As a result, manufacturing of unit elements can be easily and reasonably performed.

Herein, it is preferable that the inner expanding ring is made contact with the expanding tape from a lower direction, the outer expanding ring is made contact with the expanding tape from an upper direction, and the expanding tape is sandwiched by the dividing frame and a predetermined member, thereby applying a force with respect to the outer expanding ring in a lower direction.

### BRIEF DESCRIPTION OF THE DRAWINGS

The invention will be described with reference to the accompanying drawings, wherein like numbers reference like elements.

FIGS. 1A to 1E are each a plan view showing each part of an expanding tool according to an embodiment of the invention.

FIGS. 2A to 2C are each a plan view illustrating an expanding method according to the embodiment of the invention.

FIG. 3A is a perspective view of the expanding tool according to the embodiment of the invention, and FIG. 3B is an enlarged cross sectional view thereof.

FIG. 4A is a perspective view of an expanding tool according to another embodiment of the invention, and FIG. 4B is an enlarged cross sectional view thereof.

FIG. 5A is a perspective view of an expanding tool according to another embodiment of the invention, and FIG. 5B is an enlarged cross sectional view thereof.

FIGS. 6A to 6E are each a plan view showing each part of an expanding tool according to a conventional technique.

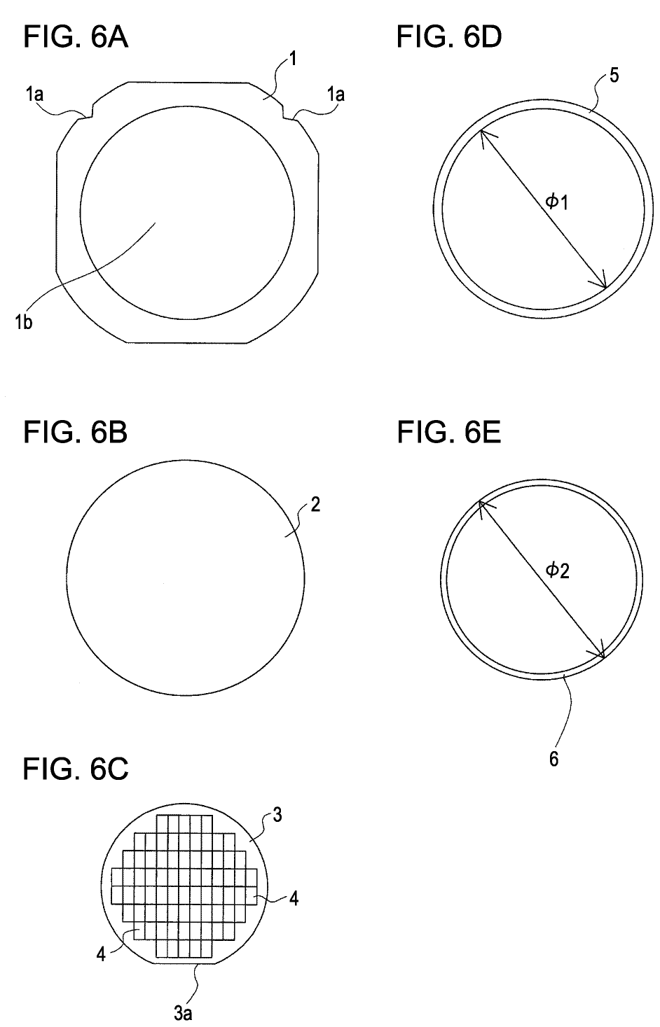

FIGS. 7A to 7E are each a plan view illustrating an expanding method according to the conventional technique.

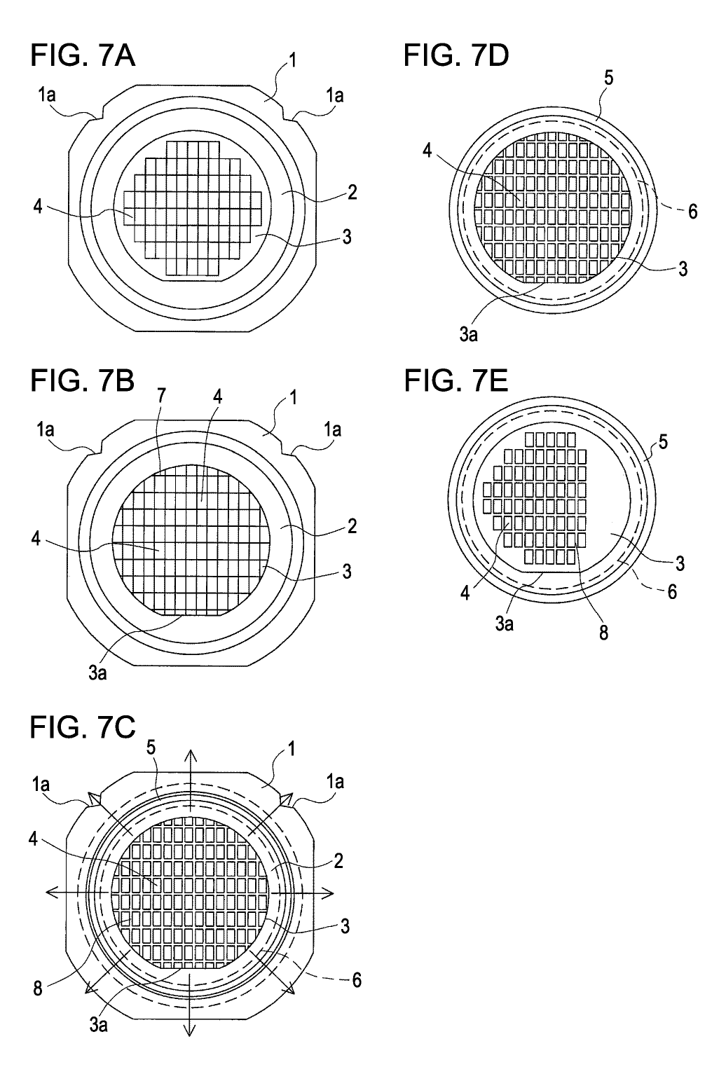

### DESCRIPTION OF EXEMPLARY EMBODIMENTS

Hereinafter, an embodiment of the invention will be described with reference to the accompanying drawings. Note that the same reference numeral is used to denote the same part as in the conventional technique.

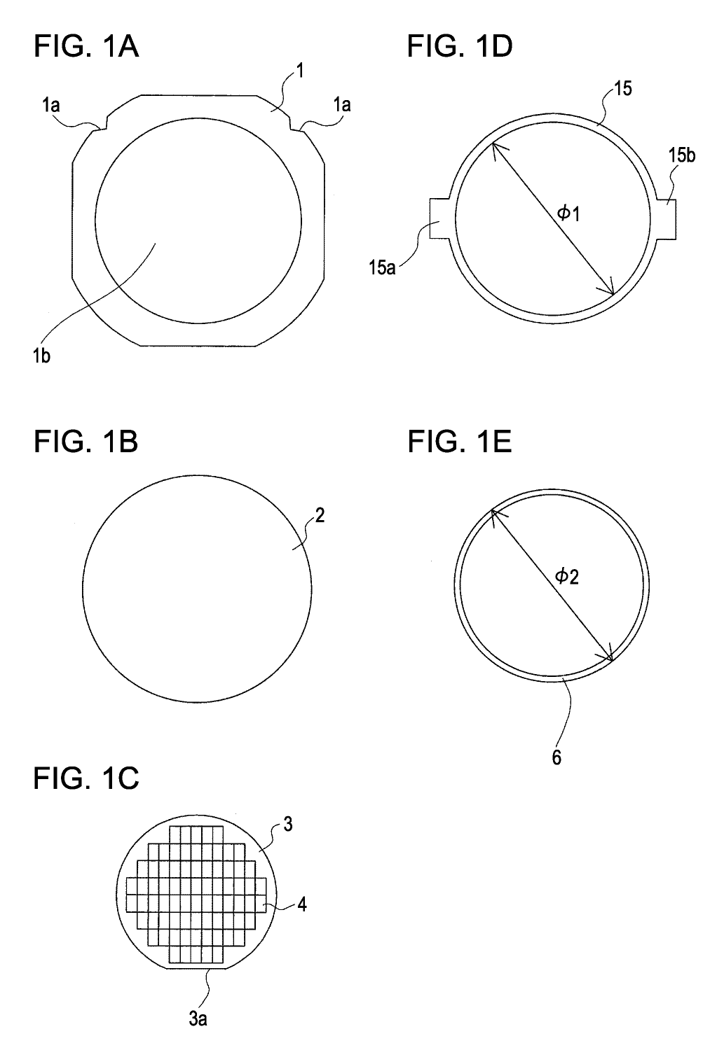

FIGS. 1A to 1E are each a plan view showing each part of an expanding tool according to the embodiment. A dividing frame 1 shown in FIG. 1A includes cutouts 1a for positioning and is generally formed by a metal such as a stainless having a circular opening 1b whose diameter is larger than an outer diameter of a wafer 3. An expanding tape 2 shown in FIG. 1B is a member having stretch properties, and an adhesive agent is applied on a surface. An orientation flat 3a for positioning is formed in a wafer 3 shown in FIG. 1C and a number of unit elements 4 such as IC chips or the like are integrally formed on the wafer 3. The diameter of the main body of an outer expanding ring 15 shown in FIG. 1D is smaller than the diameter of the opening 1b, and the outer expanding ring 15 is a circular ring member whose inner diameter is Φ1. Further, two projecting portions 15a, 15b extending in the outer direction of the diameter are formed at positions on the outer periphery of the outer expanding ring 15 to oppose to each other. As a result, the outer expanding ring 15 can be made contact with an inner margin of the dividing frame 1 via the projecting portions 15a, 15b. An inner expanding ring 6 shown in FIG. 1E is a circular ring member whose outer diameter is Φ2. Herein, the outer diameter Φ2 is slightly smaller than the inner diameter Φ1. As a result, the inner expanding ring 6 can be fitted in the outer expanding ring 15.

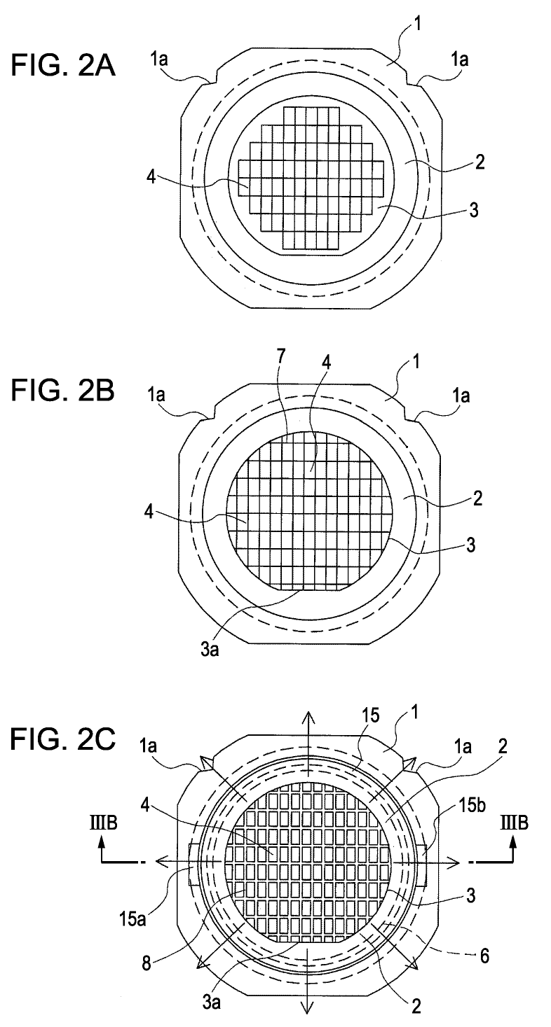

FIGS. 2A to FIG. 2C are each a plan view showing each process when an expanding is performed by using the expanding tool according to the embodiment. Each process will be described based on FIGS. 2A to FIG. 2C.

1) First, the expanding tape 2 is adhered to the dividing frame 1 having predetermined rigidity preferable for transporting, and the wafer 3 that is integrated with the unit elements 4 is mounted at a predetermined position of the expanding tape 2 (see FIG. 2A). To be more specific, a circumferential margin of the expanding tape 2 is bonded to the lower surface of the dividing frame 1 in the state where the adhesion surface of the expanding tape 2 is oriented in the upper direction. Then, the wafer 3 and the expanding tape 2 are bonded by placing the wafer 3 at a predetermined position of the adhesive face of the expanding tape 2. The process is the same as the process 1) of the conventional technique.

2) Parting lines 7 for separating the adjacent unit elements 4 are formed by a dicer, a cleaving device, or the like (see FIG. 2B). The process is the same as the process 2) of the conventional technique.

3) A tensile force is applied to the expanding tape 2 in radiation direction by inserting the outer expanding ring 15 and the inner expanding ring 6 in the expanding tape 2. By the application of the tensile force, the wafer 3 is perfectively separated along the parting lines 7 shown in FIG. 2B, and a space 8 is formed between the adjacent unit elements 4 (see FIG. 2C).

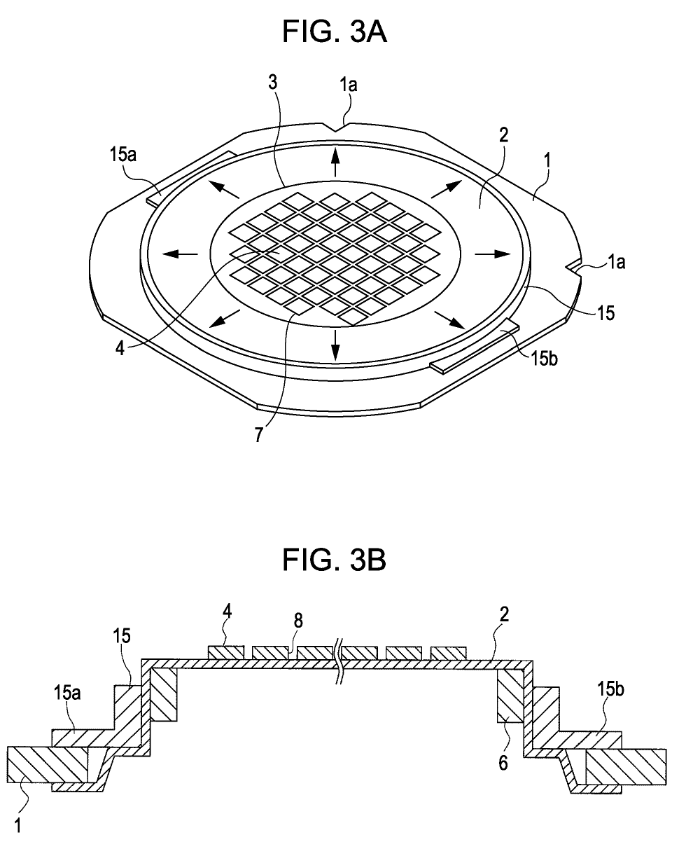

FIG. 3A is a perspective view showing a state of the process, and FIG. 3B is an enlarged cross sectional view taken along the line IIIB-IIIB of FIG. 2C. To be more specific with reference to the added FIGS. 3A, 3B, in the process, the inner expanding ring 6 is made contact with the back surface of the expanding tape 2 form the lower direction of the expanding tape 2 and the inner expanding ring 6 is lifted, and at the same time, the outer expanding ring 15 is lowered from the upper direction of the expanding tape 2 to fit the inner expanding ring 6 in the outer expanding ring 15. Herewith, the expanding tape 2 is sandwiched between the inner periphery of the outer expanding ring 15 and the outer periphery of the inner expanding ring 6. As a result, a tensile force corresponding to a raised amount of the inner expanding ring 6 is applied to the expanding tape 2 in radiation direction. Herein, a small margin is provided between the inner diameter Φ1 of the outer expanding ring 15 and the outer diameter Φ2 of the inner expanding ring 6, so that the expanding tape 2 can be favorably sandwiched between the inner periphery of the outer expanding ring 15 and the outer periphery of the inner expanding ring 6.

In the process, a tensile force is applied to the expanding tape 2 as described above. However the expanding tape 2 adhered to the dividing frame 1 is not peeled off due to the adhesion force. The expanding tape 2 may be sandwiched by the dividing frame 1 and a predetermined member such as a workbench. Herewith, the peeling off is more surely prevented. Herein, the outer diameter of the outer expanding ring 15 is smaller than the inner diameter of the dividing frame 1. However, the projecting portions 15a, 15b of the outer expanding ring 15 are made contact with an inner margin of the dividing frame 1. Accordingly the outer expanding ring 15 does not pass through the inside of the dividing frame 1 to peel the expanding tape 2 off from the dividing frame 1, and an integrated relationship between the expanding tape 2 on which the outer expanding ring 15, the inner expanding ring 6, and the wafer 3 are mounted and the dividing frame 1 is maintained. Consequently, a reaction force from the extended expanding tape 2 sandwiched by the outer expanding ring 15 and the inner expanding ring 6 is applied to the outer expanding ring 15 in the lower direction of FIG. 3B. As a result, the dividing frame 1 is pushed by the reaction force via the projecting portions 15a, 15b. However, the reaction force balances with a resisting force from the dividing frame 1 applied to the projecting portions 15a, 15b. Accordingly, the outer expanding ring 15 is integrally fixed to the dividing frame 1 with the expanding tape 2, the wafer 3, and the inner expanding ring 6.

In this manner, according to the embodiment, even after the wafer 3 is diced, the expanding tape 2 on which the unit elements 4 are bonded, the inner expanding ring 6, and the outer expanding ring 15 can be transported for a post-process without separating from the dividing frame 1. Incidentally, since a positional relationship of the wafer 3 and the unit elements 4 with respect to the dividing frame 1 is maintained in a predetermined relationship, the cutout portions 1a or the like of the dividing frame 1 can be used as a standard for positioning without change also in a post-process.

Note that, it is enough for the outer expanding ring 15 to have a contact portion that can be made contact with an inner margin of the dividing frame 1. Accordingly, it is not necessarily the case that the projecting portions 15a, 15b according to the embodiment are provided. In the embodiment, the two projecting portions 15a, 15b are provided. However, needless to say, it is not limited that the number of the projecting portions is two and a plurality of projecting portions may be provided. In this case, it is preferable that the plurality of projecting portions is disposed at an equal interval in the circumference direction of the outer expanding ring 15. This is because to average resisting forces applied to the portions.

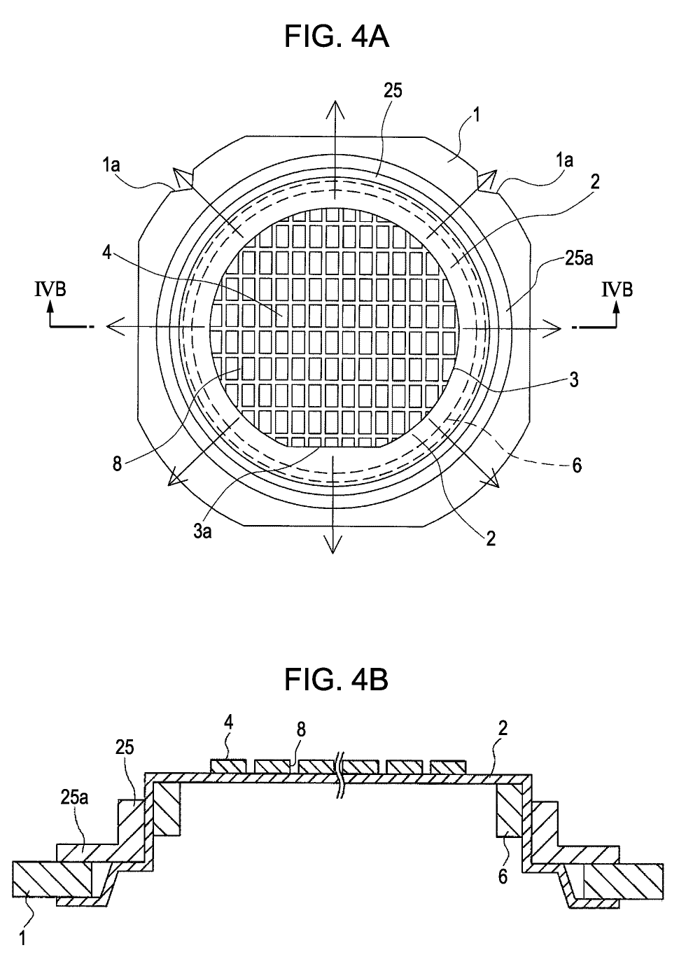

Further, as shown in a plan view of FIG. 4A, and an enlarged cross sectional view of FIG. 4B taken along the line IVB-IVB of FIG. 4A, a projecting portion 25a having the same function as the projecting portions 15a, 15b (see FIG. 1 to FIG. 3) may be provided on an outer expanding ring 25 along the entire periphery.

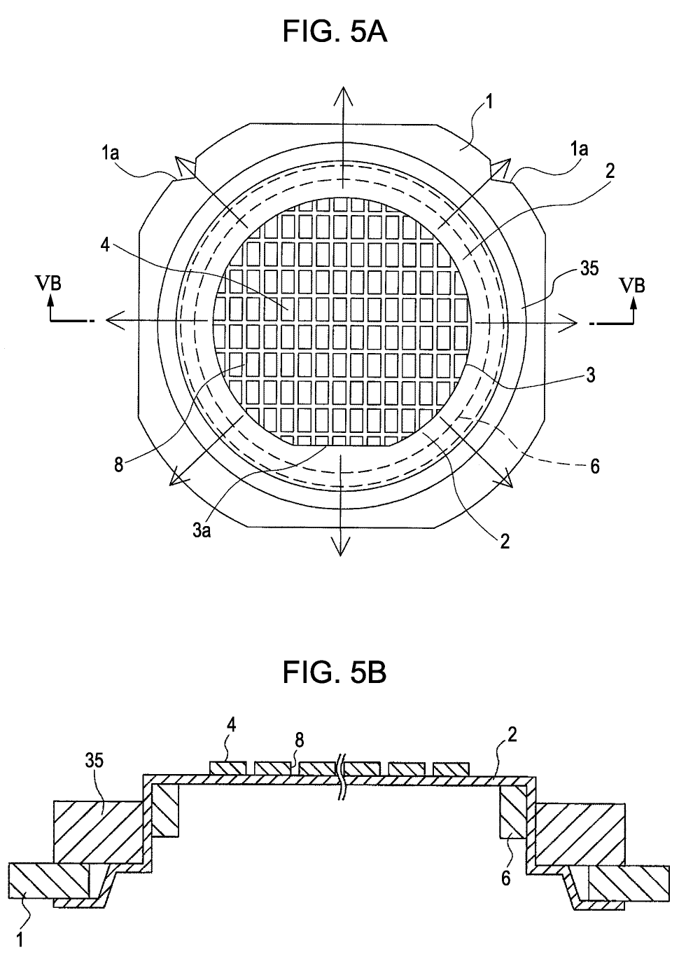

Further, as shown in a plan view of FIG. 5A, and an enlarged cross sectional view of FIG. 5B taken along the line VB-VB of FIG. 5A, the width of the ring portion of an outer expanding ring 35 itself may be widen and the inner diameter may be set smaller than the opening 1b of the dividing frame 1. Herewith, a contact portion which can be made contact with an inner margin of the dividing frame 1 can be formed. In this case, the lower surface of an outer margin of the outer expanding ring 35 becomes the contact portion.

In any case, it is enough to have a contact portion having an area made contact with the dividing frame 1 when a reflection force is applied from the expanding tape 2 sandwiched between with the inner expanding ring 6. Accordingly, the outer expanding ring may have a shape by which the outer expanding ring is made contact with an outer margin without making contact with an inner margin of the dividing frame 1 by skipping over the inner margin.

The entire disclosure of Japanese Patent Application No. 2007-220319, filed Aug. 27, 2007 is incorporated by reference herein.

What is claimed is:

1. An expanding tool used for dividing a wafer on an expanding tape by applying a radial tensile force to the expanding tape, the expanding tool comprising:
a dividing frame having a first opening;
an outer expanding ring having a contact portion that can be made contact with the dividing frame, the contact portion being provided at an outer periphery side of the outer expanding ring, and having a second opening smaller than the first opening; and
an inner expanding ring having an outer second opening.

2. The expanding tool according to claim 1, wherein
each of the first opening and the second opening has a circular shape and the inner expanding ring is a circular ring.

3. The expanding tool according to claim 1, wherein
a plurality of the contact portions are provided so as to be dispersed in a circumference direction of the outer expanding ring.

4. The expanding tool according to claim 1, wherein
the contact portion is provided along the entire periphery of the outer expanding ring.

5. The expanding tool according to claim 1, wherein
the contact portion is formed by a lower surface of an outer margin of the outer expanding ring by increasing an outer shape of the outer expanding ring than the first opening.

6. An expanding method comprising:
adhering an expanding tape on a lower surface of an inner margin of a dividing frame having a first opening whose shape is larger than an outer diameter of a wafer at a center, mounting the wafer that is integrated with a plurality of unit elements at a predetermined position of the expanding tape, and forming parting lines so that the adjacent unit elements are separated on the wafer; and
contacting an inner expanding ring with a back surface of the expanding tape from one direction of the expanding tape, and at the same time, contacting an outer expanding ring which is a member having a second opening whose inner shape is larger than an outer shape of the inner expanding ring with the expanding tape from another direction of the expanding tape, and fitting the inner expanding ring to an inside of the outer expanding ring in the state where a contact portion of the outer expanding ring is made contact with the dividing frame, thereby applying a radial tensile force to the expanding tape to dice the wafer.

7. A method for manufacturing unit elements comprising:
adhering an expanding tape on a lower surface of an inner margin of a dividing frame having a first opening whose shape is larger than an outer diameter of a wafer at a center, mounting the wafer that is integrated with a plurality of unit elements at a predetermined position of the expanding tape, and forming parting lines so that the adjacent unit elements are separated on the wafer; and
contacting an inner expanding ring with a back surface of the expanding tape from one direction of the expanding tape, and at the same time, contacting an outer expanding ring which is a member having a second opening whose inner shape is larger than an outer shape of the inner expanding ring with the expanding tape from another direction of the expanding tape, and fitting the inner expanding ring to an inside of the outer expanding ring in the state where a contact portion of the outer expanding ring is made contact with the dividing frame, thereby applying a radial tensile force to the expanding tape to dice the wafer.

8. The method for manufacturing unit elements according to claim 7, wherein
the inner expanding ring is made contact with the expanding tape from a lower direction, the outer expanding ring is made contact with the expanding tape from an upper direction, and the expanding tape is sandwiched by the dividing frame and a predetermined member, thereby applying a force with respect to the outer expanding ring in a lower direction.
